(19) United States
(12) Patent Application Publication
(10) Pub. No.: US 2007/0155145 A1
(43) Pub. Date: Jul. 5, 2007

(54) Method for forming a copper metal interconnection of a semiconductor device using two seed layers

(75) Inventor: Ji Ho Hong, Suwon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/645,523

(22) Filed: Dec. 27, 2006

(30) Foreign Application Priority Data
Dec. 29, 2005 (KR) 10-2005-0134226

(51) Int. Cl. H01L 21/20

(52) U.S. Cl. 438/584

(57) ABSTRACT

A method for forming a copper metal interconnection of a semiconductor device using two seed layers is provided. The method includes forming an inter-layer dielectric layer on a substrate, forming a damascene pattern on the inter-layer dielectric layer, forming a barrier metal layer in the damascene pattern and on an upper portion of the inter-layer dielectric layer, forming a photoresist pattern having an opening on the inter-layer dielectric layer the opening exposing the damascene pattern, forming a copper seed layer on the barrier metal layer and on the photoresist pattern, removing the photoresist pattern, and forming a copper plating layer in the damascene pattern through an electrical-chemical plating process.

### RELATED APPLICATION

This application is based upon and claims the benefit of priority to Korean Application No. 10-2005-0134226 filed on Dec. 29, 2005, the entire contents of which are incorporated herein by reference.

### TECHNICAL FIELD

The present invention relates to a method for forming a metal interconnection of a semiconductor device. More particularly, the present invention relates to a method for forming a copper metal interconnection through a damascene process.

### DESCRIPTION OF THE RELATED ART

Recently, device application technologies using various copper interconnections have been used in order to realize high-speed and high-integration semiconductor devices. Semiconductor manufacturing processes are mainly classified into a front end of the line (FEOL) process for forming a transistor on a silicon substrate, and a back end of the line (BEOL) process for forming metal interconnections. The BEOL process refers to a process of forming power supply and signal transfer paths on a silicon substrate to connect transistors to each other so as to constitute integrated circuits.

Copper (Cu), which is a material having a high EM (Electro-migration) tolerance, has been mainly used for such a BEOL process. However, since the copper (Cu) is not easily etched, but is oxidized during the interconnection process, it is difficult to pattern the copper (Cu) by employing a typical photo process technology. In order to form a copper metal interconnection, a dual damascene process technology has been developed as an alternative to conventional photo process technology. The dual damascene process forms a via and a trench in an inter-layer dielectric layer formed on a substrate, fills the via and trench with copper (Cu), and then planarizes the resultant structure through a CMP (Chemical Mechanical Polishing) process.

Hereinafter, the conventional dual damascene process will be described with reference to FIGS. 1A to 1D.

First, as shown in FIG. 1A, a barrier insulating layer 14 is formed on a first inter-layer dielectric layer 10 formed with a lower metal interconnection 12. Barrier insulating layer 14 may be used as an etch stop layer during a process of forming a damascene pattern on an upper part of barrier insulating layer 14. Barrier insulating layer 14 includes a silicon nitride layer (SiN) or a silicon carbide (SiC) layer. A second inter-layer dielectric layer 16 is formed on barrier insulating layer 14. After forming second inter-layer dielectric layer 16, a damascene pattern including a via 16a and a trench 16b is formed in second inter-layer dielectric layer 16 by using barrier insulating layer 14 as an etching stop layer. Thereafter, after removing a portion of barrier insulating layer 14, which is exposed by via 16a, a barrier metal layer 18 is formed on the entire surface of second inter-layer dielectric layer 16. Barrier metal layer 18 is uniformly deposited along an inner wall of via 16a and trench 16b.

As shown in FIG. 1B, a copper seed layer 19 is formed on barrier metal layer 18. As shown in FIG. 1C, a copper layer 20, which is buried in via 16a and trench 16b, is formed on copper seed layer 19 through electro-chemical plating (ECP). As shown in FIG. 1D, copper layer 20 is polished through a chemical-mechanical polishing(CMO) process until second inter-layer dielectric layer 16 is exposed, thereby completely forming a copper metal interconnection 22.

Since the copper seed layer is typically formed as a signal layer when the ECP process is performed, and the seed layer formed on a planar surface provided on the inter-layer dielectric layer and in the damascene pattern has uniform resistivity, both a wide pattern and a narrow pattern have the same current density. In addition, organic additives such as an accelerator and a suppressor are added to a copper plating solution in order to improve gap-fill characteristics for a narrow pattern. As copper plating is performed, the accelerator is lifted from the bottom to the top of the damascene pattern. Accordingly, an amount of the accelerator locally increases in an area where a great number of narrow patterns is formed at a high pattern density, and the amount of the accelerator is relatively lowered in an area where a wide pattern is formed at a low pattern density.

FIG. 2A shows copper plating layers formed in an area where great numbers of narrow patterns 20b are formed (that is, an area having high pattern density) and in an area where a wide pattern 20a is independently formed (that is, an area having low pattern density). As shown in FIG. 2A, as plating is performed, the copper atoms are concentrated on the area having the high pattern density due to the cohesion of an accelerator and a copper seed layer formed on a planar surface provided on the pattern, so humps are generated. In contrast, since the area of an exposed copper seed layer is relatively narrow in the area having the low pattern density, and the content of the accelerator is reduced, the copper plating layer is insufficiently formed. Accordingly, if additional plating must be performed, wide pattern 20a formed in the low pattern density area may be completely gap-filled. In general, such additional plating process is called bulk plating. In this case, although this bulk plating layer is removed by a following CMP process, since the manufacturing time increases proportionally to the thickness (Ts) of the bulk plating layer, this is not preferred in view of manufacturing costs of the semiconductor device.

### BRIEF SUMMARY

Consistent with the present invention there is provided a method for forming a copper metal interconnection, capable of remarkably reducing the degree of bulk planting, which must be performed, by improving a gap-fill speed of copper buried in a damascene pattern.

Also, consistent with the present invention, there is provided a method for forming a copper metal interconnection of a semiconductor device, including forming an inter-layer dielectric layer on a semiconductor substrate, forming a damascene pattern on the inter-layer dielectric layer, forming a barrier metal layer in the damascene pattern and on an upper portion of the inter-layer dielectric layer, forming a photoresist pattern having an opening on the inter-layer dielectric layer the opening exposing the damascene pattern, forming a copper seed layer on the barrier metal layer and on the photoresist pattern, removing the photoresist pattern, and forming a copper plating layer in the damascene pattern through an electrical-chemical plating process.

A notch can be formed in a lower part of the photoresist pattern. The photoresist pattern can be removed through a laser lift-off scheme by using the notch. Particularly, it is preferred that the barrier metal layer include a material having a resistivity higher than resistivity of copper (Cu). The surface of the wafer is planarized through a chemical mechanical polishing process.

### BRIEF DESCRIPTION OF THE DRAWINGS

FIGS. 1A to 1D are sectional views showing a method for forming a conventional copper metal interconnection through a dual damascene process;

FIG. 2A is a sectional view showing a process of burying a copper plating layer in a damascene pattern according to the related art, and FIG. 2B is a sectional view showing a state in which the copper plating layer is completely buried in the damascene pattern;

FIGS. 3A to 3G are sectional views showing a method for forming a copper metal interconnection consistent with the present invention; and

FIGS. 4A and 4B are sectional views showing a process for forming a copper metal layer through a method for forming a copper metal interconnection consistent with the present invention, in which FIG. 4A is a sectional view showing a process of filling a damascene pattern with copper, and FIG. 4B is a sectional view showing a state in which copper is completely buried in the damascene pattern.

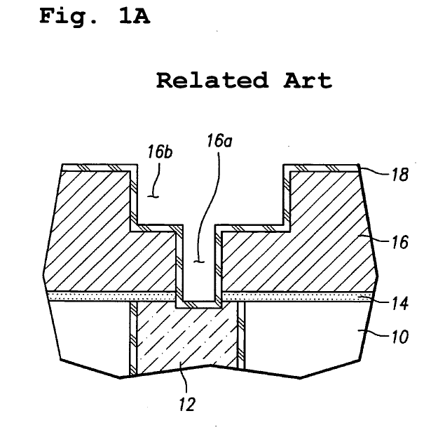

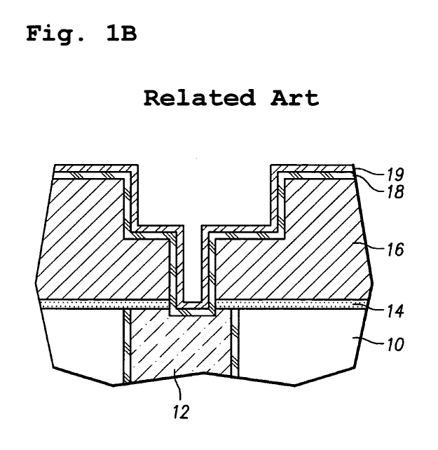

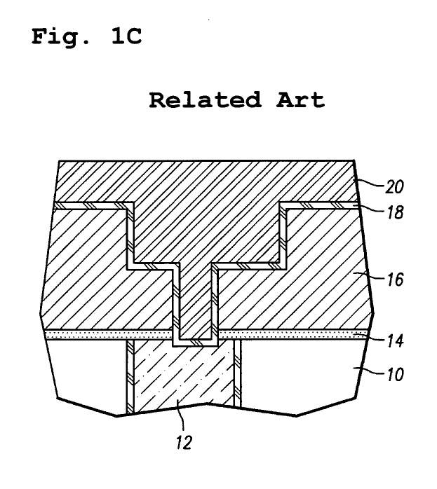

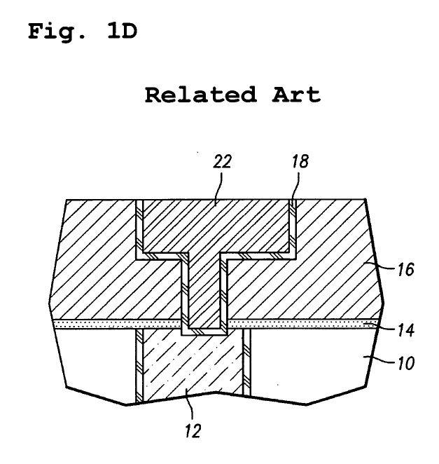

### DETAILED DESCRIPTION

Hereinafter, a preferred embodiment of a method for forming a copper metal interconnection consistent with the present invention will be described with reference to accompanying drawings.

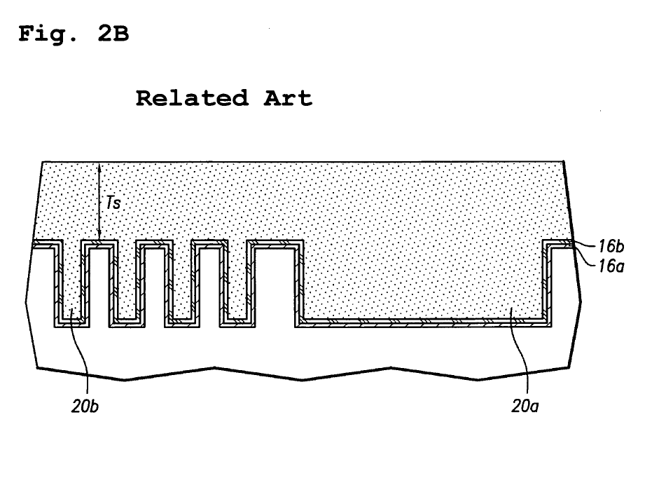

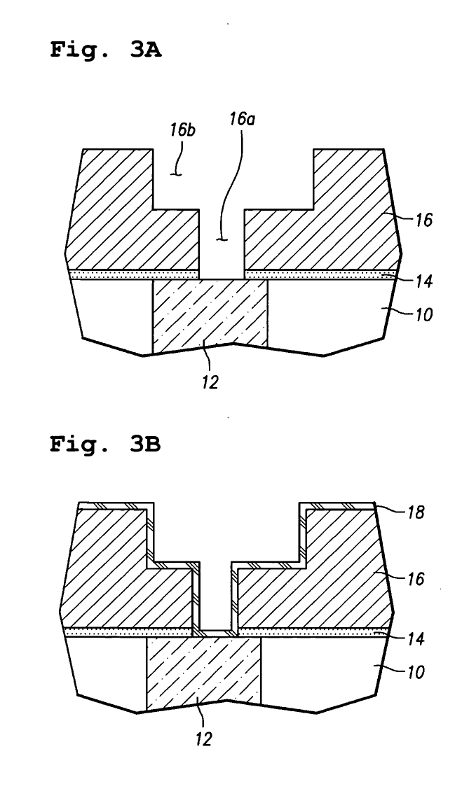

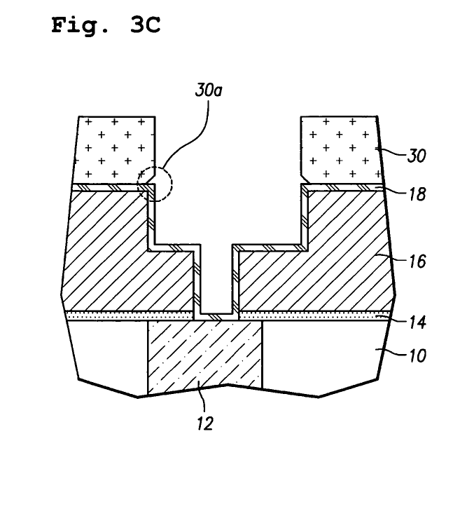

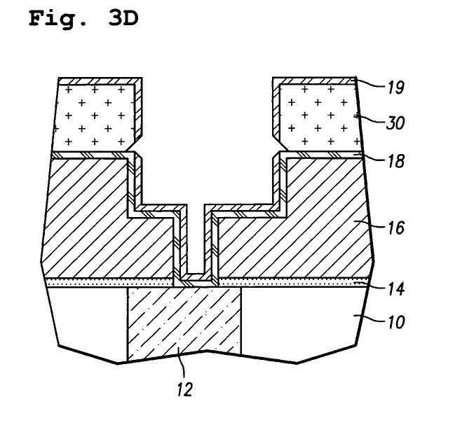

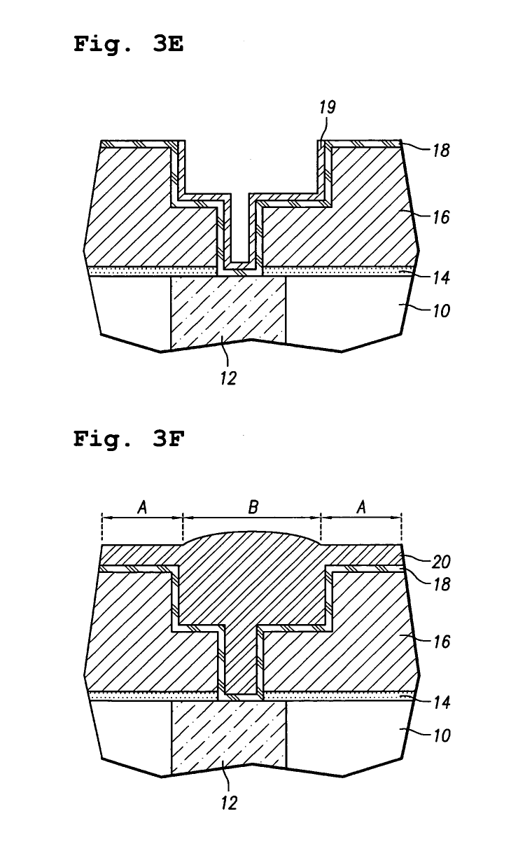

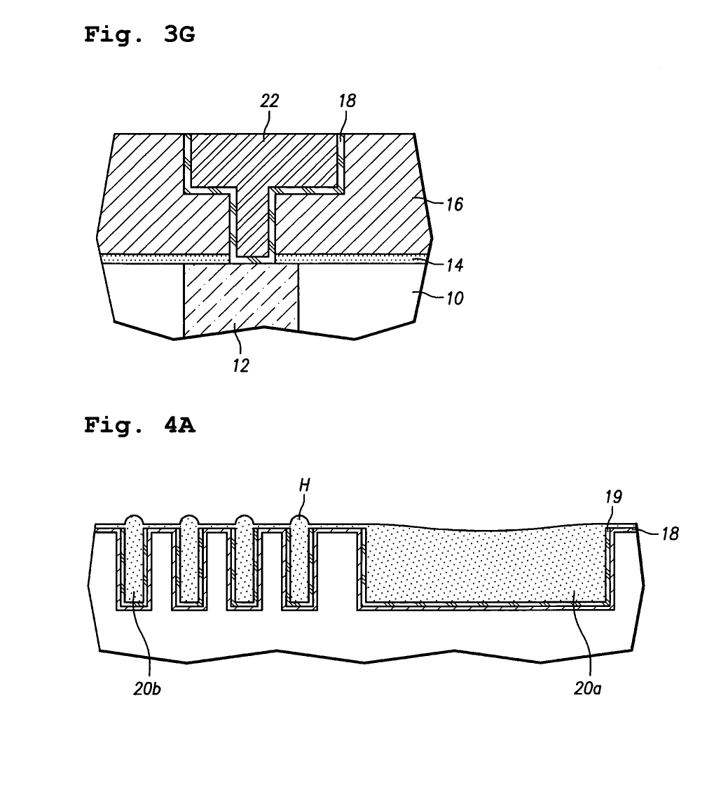

As shown in FIG. 3A, a barrier insulating layer 14 is formed on a first inter-layer dielectric layer 10 formed with a lower metal interconnection 12. Barrier inter-layer dielectric layer 14 serves as an etch stop layer during a process for forming a damascene pattern at an upper part of barrier inter-layer dielectric layer 14. Barrier inter-layer dielectric layer 14 includes a silicon nitride (SiN) layer and a silicon carbide (SiC) layer. A second inter-layer dielectric layer 16 is formed on barrier insulating layer 14. After forming second inter-layer dielectric layer 16, a damascene pattern including a via 16a and a trench 16b is formed in second inter-layer dielectric layer 16 by using barrier insulating layer 14 as an etch stop layer. A portion of barrier insulating layer 14 exposed by the via 16a is removed so that an upper surface of lower metal interconnection 12 is exposed.

Then, as shown in FIG. 3B, a barrier metal layer 18 is formed on the entire surface of second inter-layer dielectric layer 16. In this case, barrier metal layer 18 is uniformly formed on an inner wall of via 16a and trench 16b and the exposed upper surface of lower metal interconnection 12. Barrier metal layer 18 generally blocks the diffusion of copper (Cu). In particular, consistent with the present invention, barrier metal layer 18 includes a material having a resistivity higher than the resistivity of copper (Cu).

As shown in FIG. 3C, a photoresist pattern 30, which exposes the damascene pattern, is formed on an upper part of second inter-layer dielectric layer 16 in which the damascene pattern are not formed. In other words, the upper part of second inter-layer dielectric layer 16 in the vicinity of the damascene pattern is masked by photoresist pattern 30. In addition, notches 30a are created at edge areas in which photoresist pattern 30 makes contact with second inter-layer dielectric layer 16. Notch 30a can be easily created if conditions of a typical photo process are changed. The reason for forming notch 30a is to more easily remove photoresist pattern 30a during the following process.

As shown in FIG. 3D, a copper seed layer 19 is formed on the entire surface of a wafer. Copper seed layer 19 is uniformly formed on an outer surface of photoresist pattern 30 and in an inner surface of the damascene pattern.

If photoresist pattern 30 is removed, a dual seed layer shown in FIG. 3E is formed. In this case, if notch 30a is formed in the lower part of photoresist pattern 30, photoresist pattern 30 can be removed through a laser lift-off scheme, so that photoresist pattern 30 can be easily removed.

Meanwhile, if photoresist pattern 30 is removed, since a portion of copper seed layer 19 formed on photoresist pattern 30 is removed, barrier metal layer 18 and copper seed layer 19 are formed in the inner wall of the damascene pattern, and only barrier metal layer 18 is formed on the upper surface of second inter-layer dielectric layer 16 in the vicinity of the damascene pattern. In this case, since barrier metal layer 18 includes a material having resistivity higher than that of copper while serving as a seed layer, a current density in the damascene pattern formed with copper seed layer 19 is greater than that on the upper surface of second inter-layer dielectric layer 16 formed only with barrier metal layer 18.

Accordingly, as shown in FIG. 3F, since a plating rate of an inner part (B) of the damascene pattern is higher than that of an area (A) adjacent to the damascene pattern, many more copper ions may be plated in inner part (B) of the damascene pattern when performing an electro-chemical plating (ECP) scheme. Referring to 2A, in the case of a wide pattern, since a plating rate is relatively lower in the inner part of the wide pattern than the area adjacent to the wide pattern, a gap-fill speed of the wide pattern is reduced. However, as shown in FIG. 3F, since a plating rate in the inner part of a damascene pattern formed with a seed layer including low-resistivity copper is higher than a plating rate in the area adjacent to the damascene pattern, which is formed only with a barrier metal layer 18 including high-resistivity copper, the gap fill is more quickly performed in even the wide pattern.

As shown in FIG. 3G, plated copper layer 20 is polished through a chemical mechanical polishing (CMP) scheme until insulating layer 16 is exposed, thereby completely forming copper metal interconnection 22.

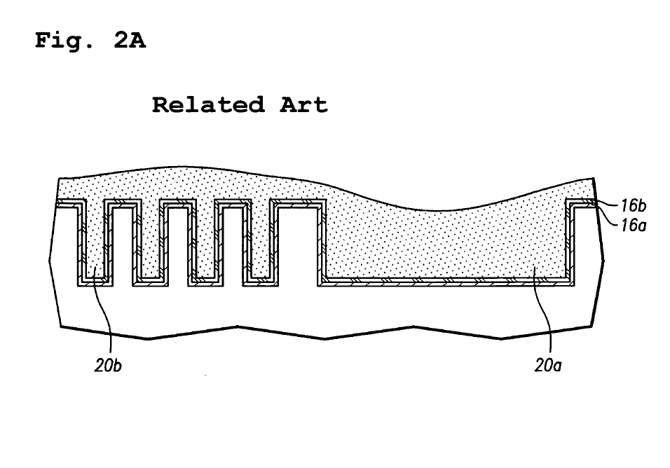

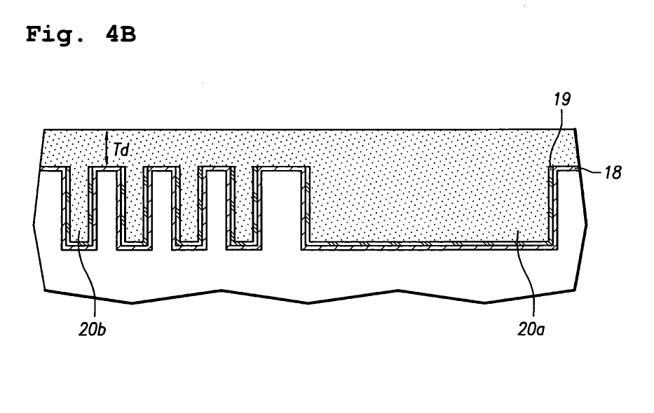

FIG. 4A is a view showing the state of the substrate after performing an electro-chemical plating (ECP) scheme. Referring to FIG. 4A, humps may be shown in an area formed with narrow patterns 20b at a high pattern density. This is because relatively many copper atoms are plated due to the cohesion of accelerators. However, when comparing FIG. 4A with FIG. 2A, it can be understood that gap fill is more quickly performed in a wide pattern 20a of FIG. 4A. Although bulk plating is required in order to completely gap-fill the inner part of wide pattern 20a, the thickness (Td) of a bulk plating layer consistent with the present invention is remarkably reduced as compared with the thickness (Ts) of a bulk plating layer required through a conventional scheme when comparing FIG. 2B with FIG. 4B. Accordingly, not only is the process time required for the bulk plating reduced, but the time required for chemical mechanical process (CMP), is also reduced as discussed below.

Consistent with the present invention, a seed layer having low resistivity is formed in the inner part of the damascene pattern, and a seed layer having a high resistivity is formed in the vicinity of the damascene pattern, so it is possible to improve a copper plating rate in the damascene pattern. Therefore, since a difference between a gap-fill speed of an area having a high pattern density and a gap-fill speed of an area having a low pattern density is reduced, the amount of bulk plated coppers is minimized. As a result, the manufacturing time required for plating may be reduced, and the time of the following CMP process can be reduced. The method for forming a copper metal interconnection consistent with the present invention is adaptable for a single damascene process as well as a dual damascene process.

It will be apparent by those skilled in the art that various changes in form and details may be made therein without departing from the spirit and scope consistent with the invention as defined by the appended claims.

What is claimed is:

1. A method for forming a copper metal interconnection of a semiconductor device, comprising:
forming an inter-layer dielectric layer on a substrate;
forming a damascene pattern on the inter-layer dielectric layer;
forming a barrier metal layer in the damascene pattern and on an upper pattern part of the inter-layer dielectric layer;
forming a photoresist pattern having an opening on the inter-layer dielectric layer the opening exposing the damascene pattern;
forming a copper seed layer on the barrier metal layer and on the photoresist pattern;
removing the photoresist pattern; and
forming a copper plating layer in the damascene pattern through an electrical-chemical plating process.

2. The method according to claim 1, further comprising forming a notch in a lower portion of the photoresist pattern.

3. The method according to claim 2, wherein the notch is formed at an edge area in which the photoresist pattern wherein the photoresist makes contact with the inter-layer dielectric layer at the edge area.

4. The method according to claim 2, wherein the photoresist pattern is removed through a laser lift-off process.

5. The method according to claim 1, wherein the barrier metal layer includes a material having a resistivity higher than the resistivity of copper (Cu).

6. The method according to claim 1, further comprising removing a portion of the copper plating layer formed on an upper part of the inter-layer dielectric layer through a chemical mechanical polishing process.
